(19) United States
(12) Patent Application Publication
(10) Pub. No.: US 2026/0128611 A1
(43) Pub. Date: May 7, 2026

(54) INTEGRATED CIRCUIT WITH POWER LOSS PROTECTION FUNCTION

(71) Applicant: Chengdu Monolithic Power Systems Co., Ltd., Chengdu (CN)

(72) Inventors: Hang Yang, Chengdu (CN); Bo Li, Chengdu (CN); Haitang Wang, Chengdu (CN); Pengjie Lai, San Jose, CA (US)

(21) Appl. No.: 19/379,048

(22) Filed: Nov. 4, 2025

(30) Foreign Application Priority Data
Nov. 5, 2024 (CN) 202411565018.6

(51) Int. Cl. H02J 7/00; H02J 7/34

(52) U.S. Cl. CPC H02J 7/96; H02J 7/345; H02J 7/82; H02J 2207/50

(57) ABSTRACT

An integrated circuit with power loss protection function, including a bus terminal configured to provide a bus voltage, an energy storage terminal configurable to be coupled to a power loss protection capacitor, a charging circuit coupled between the bus terminal and the energy storage terminal, and a capacitance monitoring circuit. The charging circuit includes a first charging path, and based on the bus voltage, provides a first constant charging current to charge the power loss protection capacitor during a first constant charging period in a startup process of the integrated circuit. The capacitance monitoring circuit monitors the voltage across the power loss protection capacitor in the charging period of the startup process of the integrated circuit to obtain a parameter for calculating the capacitance value of the power loss protection capacitor.

### CROSS-REFERENCE

The present application claims priority to, and the benefit of, Chinese Application No. 202411565018.6 filed on Nov. 5, 2024, which is incorporated herein by reference in its entirety.

### TECHNICAL FIELD

This present application generally relates to electronic circuits, more particularly but not limited to integrated circuits with power loss protection function and methods for monitoring capacitance values of power loss protection capacitors.

### BACKGROUND

In certain conventional power management circuits for uninterrupted power supply applications, a backup power source is typically provided to sustain power delivery to an application device during unexpected loss of external power supply. For example, in a conventional switching power supply for providing a bus voltage to a downstream device such as a DC-DC converter for supplying a Solid State Driver (SSD), a power loss protection capacitor with relatively high nominal voltage commonly serve as the backup power source when a preset condition is met (e.g., when the bus voltage drops to a release threshold).

According to the energy storage principles of the capacitor, the energy stored in a capacitor is proportional to the capacitance value of the capacitor. However, as the capacitor ages over time, the capacitance value decreases and the energy it can store decreases accordingly. In some applications, when the energy stored in a power loss protection capacitor decreases to a certain level, it may no longer function as the backup power source. Therefore, it is necessary to effectively monitor the capacitance value of the power loss protection capacitor while reducing the interference with normal circuit operations.

### SUMMARY

There has been provided, in accordance with an embodiment of the present invention, an integrated circuit with power loss protection function, including: a bus terminal, an energy storage terminal, a charging circuit and a capacitance monitoring circuit. The bus terminal is configured to provide a bus voltage. The energy storage terminal is configurable to be coupled to a power loss protection capacitor. The charging circuit is coupled between the bus terminal and the energy storage terminal and is configured to charge the power loss protection capacitor using the bus voltage when the power loss protection capacitor is coupled to the energy storage terminal. The charging circuit includes a first charging path configured to charge the power loss protection capacitor based on the bus voltage during a charging period in a startup process of the integrated circuit, and the charging period includes at least a first constant charging period during which the first charging path is further configured to at least provide a first constant charging current to charge the power loss protection capacitor, such that a voltage across the power loss protection capacitor rises at a first fixed slope. The capacitance monitoring circuit is configured to monitor a voltage across the power loss protection capacitor when the power loss protection capacitor is coupled to the energy storage terminal, in the charging period of the startup process of the integrated circuit, to obtain a parameter for calculating a capacitance value of the power loss protection capacitor.

Another embodiment of the present invention provides a method for capacitance monitoring for a power loss protection capacitor. The method is executed by an integrated circuit with power loss protection function and includes the following steps. Charging the power loss protection capacitor based on the bus voltage during a charging period in the startup process of the integrated circuit, and the charging period includes at least a first constant charging period. Providing a first constant charging current to charge the power loss protection capacitor during the first constant charging period, such that a voltage across the power loss protection capacitor rises at the first fixed slope. Monitoring a voltage across the power loss protection capacitor in the charging period of the startup process of the integrated circuit, to obtain a parameter for calculating a capacitance value of the power loss protection capacitor.

It should be understood that the description described in this section is not intended to identify key or important features of the embodiments of the present application, nor is it intended to limit the scope of the present application. Other features of the present application will be easily understood from the following specification.

### BRIEF DESCRIPTION OF DRAWINGS

For a better understanding of the present invention, embodiments thereof will be described with reference to below drawings, which are provided for illustrative purpose only. The drawings generally illustrate only certain features of the embodiments and are not necessarily drawn to scale.

FIG. 1 illustrates a block diagram of a power management circuit with power loss protection function in accordance with an embodiment of the present invention.

FIG. 2 illustrates a circuit schematic of the power management circuit shown in FIG. 1 in accordance with an embodiment of the present invention.

FIG. 3 illustrates a waveform diagram of an energy storage voltage during the process of charging the power loss protection capacitor in accordance with an embodiment of the present invention.

FIG. 4 illustrates a waveform diagram of an energy storage voltage during the process of charging the power loss protection capacitor with a constant current via a first charging path in accordance with another embodiment of the present invention.

FIG. 5 illustrates a waveform diagram of an energy storage voltage during the process of charging the power loss protection capacitor with a constant current via the first charging path in accordance with still another embodiment of the present invention.

FIG. 6 illustrates a waveform diagram of an energy storage voltage during the process of charging the power loss protection capacitor with a constant current via the first charging path in accordance with yet another embodiment of the present invention.

FIG. 7 illustrates a flowchart of a method for monitoring the capacitance value of a power loss protection capacitor in accordance with an embodiment of the present invention.

### DETAILED DESCRIPTION

Various embodiments of the present invention will now be described. The following description includes specific details such as exemplary circuits and representative values of the circuit components to provide a thorough understanding of the embodiments. However, it will be understood by those skilled in the relevant art that the present disclosure may be performed without one or more of such specific details, or with alternative methods, components, materials, etc. In other instances, well-known structures, materials, processes, or operations are not shown or described in detail to avoid obscuring aspects of the present disclosure.

Throughout the specification and claims, the phrases “in an embodiment”, “in some embodiments”, “in an implementation”, and “in some implementations” used include combinations and sub-combinations of the various features described herein, as well as variations and modifications thereof. These phrases used herein do not necessarily refer to the same embodiment, though they may. Those skilled in the art should understand that the meaning of the above terms does not necessarily limit these terms, but merely provide illustrative examples for the terms. Note that when a component is “connected to” or “coupled to” another component, it means the component is either directly connected or coupled to the other component or indirectly connected or coupled to the other element via another component. Specific features, structures, or characteristics may be included in an integrated circuit, an electronic circuit, a combinatorial logic circuit or other suitable components providing the described function. Additionally, it should be understood that the drawings provided herewith for explanation purposes to those of ordinary skill in the art and are not necessarily drawn to scale.

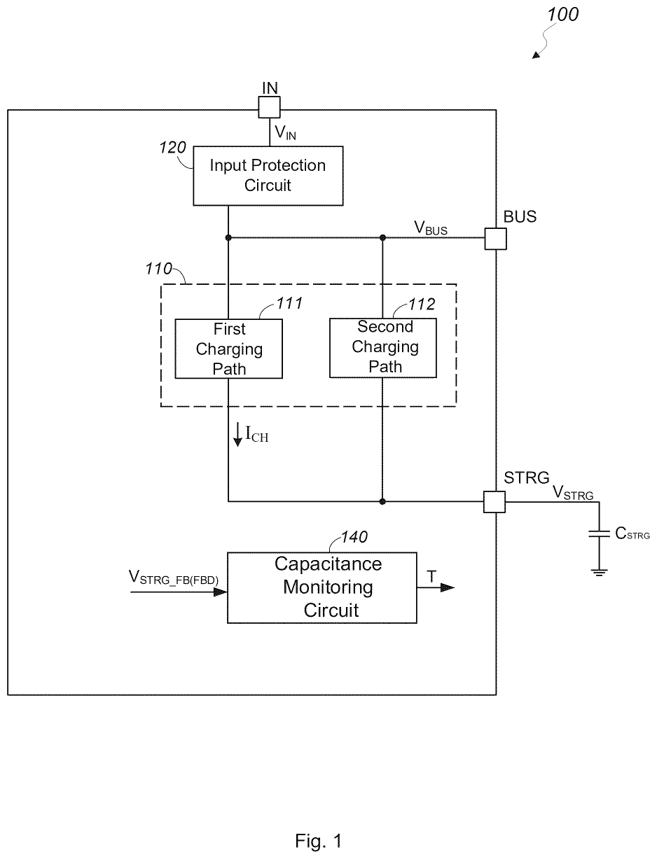

FIG. 1 illustrates a block diagram of a power management circuit 100 with power loss protection function according to an embodiment of the present invention. In an embodiment, the power management circuit 100 may include multiple circuits packaged together as an integrated circuit chip.

As shown in FIG. 1, the power management circuit 100 includes an input terminal IN, a bus terminal BUS, and an energy storage terminal STRG. For simplicity of illustration, FIG. 1 omits other terminals unrelated to the present invention.

The power management circuit 100 receives an input voltage V_{IN} at the input terminal IN. In an embodiment, during the normal operation of the power management circuit 100, the power management circuit 100 connects the input voltage V_{IN} from the input terminal IN to the bus terminal BUS, and provides a bus voltage V_{BUS} on the bus terminal BUS. The bus voltage V_{BUS} may be supplied to an application device (not shown), such as a solid-state drive (SSD), a hard disk drive (HDD), or other devices requiring power loss protection. In an example, the application device includes a volatile energy storage device (e.g., a random-access memory, RAM) that requires backup power to store data to non-volatile energy storage device (e.g., non-volatile RAM, NVRAM) when the power loss occurs.

In the embodiment shown in FIG. 1, the energy storage terminal STRG is connected to a power loss protection capacitor C_{STRG}. For example, the power loss protection capacitor C_{STRG} may be an electrolytic capacitor, a stacked capacitor, a tantalum capacitor, an electric double-layer capacitor, or a polymer capacitor. It should be understood that in another embodiment, the energy storage terminal STRG may be connected to multiple power loss protection capacitors. In this way, depending on practical application requirements, the power management circuit 100 may further include two or more energy storage terminals to be respectively connected to two or more sets of power loss protection capacitors.

One of the functions of the power management circuit 100 is to charge the power loss protection capacitor C_{STRG} with the bus voltage V_{BUS}. It should be understood that, depending on actual design requirements, the power management circuit 100 may alternatively charge the power loss protection capacitor C_{STRG} using other voltages (e.g., the input voltage V_{IN}), and the present disclosure is not so limited.

As shown in FIG. 1, the power management circuit 100 further includes a charging circuit 110 coupled between the bus terminal BUS and the energy storage terminal STRG for charging the power loss protection capacitor C_{STRG}. For example, during the startup process of the power management circuit 100 when the power loss protection capacitor C_{STRG} has not yet stored energy (or contains only a small amount of initial energy), the power management circuit 100 may use the charging circuit 110 to charge the power loss protection capacitor C_{STRG} connected to the energy storage terminal STRG, causing the voltage across the power loss protection capacitor C_{STRG} to increase to a set voltage V_{SET} (also referred to as the target voltage of the power loss protection capacitor C_{STRG}). For another example, during the normal operation of the power management circuit 100, when the voltage across the power loss protection capacitor C_{STRG} decreases below a predetermined threshold due to inevitable power loss, the power management circuit 100 may use the charging circuit 110 to charge the power loss protection capacitor C_{STRG}, thereby maintaining the voltage across the power loss protection capacitor C_{STRG} at the set voltage V_{SET}. When a system power loss occurs (e.g., disconnected from the input voltage V_{IN}), the power management circuit 100 may then use the energy stored in the power loss protection capacitor C_{STRG} to generate the bus voltage V_{BUS} at the bus terminal BUS, thereby sustaining power delivery to the application device.

In an embodiment, the power management circuit 100 may further include an input protection circuit 120 coupled between the input terminal IN and the bus terminal BUS. In an embodiment, the input protection circuit 120 may include two transistors, such as two MOSFETs, and the two transistors are connected in such a manner that their body diodes are connected back to back (for convenience of description, these two transistors may be referred to hereinafter as the two transistors connected back to back). During normal charging period, the two transistors connected back to back are both turned on, thereby connecting the input terminal IN to the bus terminal BUS to provide the bus voltage V_{BUS}. When a power loss occurs, the two transistors connected back to back are both turned off, disconnecting the connection between the input terminal IN and the bus terminal BUS, thereby preventing a current from the power loss protection capacitor C_{STRG} from flowing back to upstream devices at the input terminal IN and reducing additional power loss.

According to embodiments of the present invention, in an application where the set voltage V_{SET} (or target voltage) of the power loss protection capacitor C_{STRG} exceeds the bus voltage V_{BUS}, to avoid an inrush current, the power loss protection capacitor C_{STRG} can first be charged by a constant charging current I_{CH} so that the power loss protection capacitor C_{STRG} can reach an intermediate charging voltage V_{M} (e.g., where the intermediate charging voltage V_{M} is equal to or close to the bus voltage V_{BUS}), then the power loss protection capacitor C_{STRG} is charged by a boost converter circuit to the set voltage V_{SET} exceeding the bus voltage V_{BUS}. For example, “close to the bus voltage V_{BUS}” as mentioned herein may include voltages below the bus voltage V_{BUS} but with a difference less than a predetermined threshold. For instance, in a practical implementation where the bus voltage V_{BUS} is 12 V, the intermediate charging voltage V_{M} close to the bus voltage V_{BUS} may be 11.7 V, in this case, the predetermined threshold is 0.3 V.

As shown in FIG. 1, the charging circuit 110 includes a first charging path (also referred to as a constant current charging path) 111 and a second charging path (also referred to as a boost charging path) 112. In an embodiment, the first charging path 111 is configured to provide a constant charging current I_{CH} to charge the power loss protection capacitor C_{STRG}, while the second charging path 112 is configured to charge the power loss protection capacitor C_{STRG} using a boost converter circuit. It should be understood that when the set voltage V_{SET} of the power loss protection capacitor C_{STRG} IS equal to or lower than the bus voltage V_{BUS}, the charging circuit 110 may charge the power loss protection capacitor C_{STRG} and boost the energy storage voltage V_{STRG} across the power loss protection capacitor C_{STRG} to the set voltage V_{SET} solely via the first charging path 111.

In some embodiments where the set voltage V_{SET} is higher than the bus voltage V_{BUS}, the first charging path 111 may draw power from the bus terminal BUS during a first charging phase (e.g., supplied by the aforementioned bus voltage V_{BUS}) and provide a constant charging current I_{CH} to charge the power loss protection capacitor C_{STRG}, thereby elevating the voltage across the power loss protection capacitor C_{STRG} (i.e., the voltage at the energy storage terminal STRG) to the intermediate charging voltage V_{M}. For example, the first charging phase (also referred to as a pre-charging phase) may refer to an operation period or an operation mode during which the power management circuit 100 boosts the voltage at the energy storage terminal STRG (e.g., which equals to the energy storage voltage V_{STRG} across the power loss protection capacitor C_{STRG}) from an initial voltage (e.g., 0 V) below the intermediate charging voltage V_{M} to the intermediate charging voltage V_{M} through, for example, the first charging path 111. In an embodiment, the power management circuit 100 may further include a current control circuit (not shown) for regulating a magnitude of the constant charging current I_{CH}.

In an embodiment, after the energy storage voltage V_{STRG} across the power loss protection capacitor C_{STRG} is increased to the intermediate charging voltage V_{M} via the first charging path 111, the charging circuit 110 subsequently boosts the voltage at the energy storage terminal STRG from the intermediate charging voltage V_{M} to the set voltage V_{SET} during a second charging phase via the second charging path 112. According to an embodiment of the present invention, the second charging phase may refer to a charging period after the first charging phase ends. For example, the second charging phase may refer to an operation period or an operation mode during which the voltage at the energy storage terminal STRG is increased from the intermediate charging voltage V_{M} to the set voltage V_{SET} via the second charging path 112. In an embodiment, the second charging path 112 may include a boost converter circuit. For example, the second charging path 112 can be configured to control the ON and OFF of a switching element based on a control signal, thereby converting the bus voltage V_{BUS} to a higher voltage for charging the power loss protection capacitor C_{STRG} to the set voltage V_{SET}.

In an embodiment, the first charging phase and the second charging phase may be, for example, periods in the startup process of the power management circuit 100. Generally, in practical applications, when the power management circuit 100 is initially turned on/enabled or initially been connected to an input power source, which can be referred to as initially powered on, the power loss protection capacitor C_{STRG} has not yet store energy (or contains only initial energy). Therefore, the power management circuit 100 needs to charge the power loss protection capacitor C_{STRG} by the charging circuit 110 during the startup process to boost the energy storage voltage V_{STRG} across the power loss protection capacitor C_{STRG} to the set voltage V_{SET}, thereby ensuring the power loss protection capacitor C_{STRG} can provide a backup power for subsequently unexpected events such as power loss.

In some embodiments, as illustrated in FIG. 1, the first charging path 111 and the second charging path 112 are two independent paths. However, in other embodiments, the two paths may share common components, meaning that in other embodiments, certain elements may be part of both the first charging path 111 and the second charging path 112. It should be understood that the first charging path 111 in the embodiments of the present invention may include any constant current charging circuit capable of charging the power loss protection capacitor C_{STRG} by a constant current, and the second charging path 112 may include any boost charging circuit.

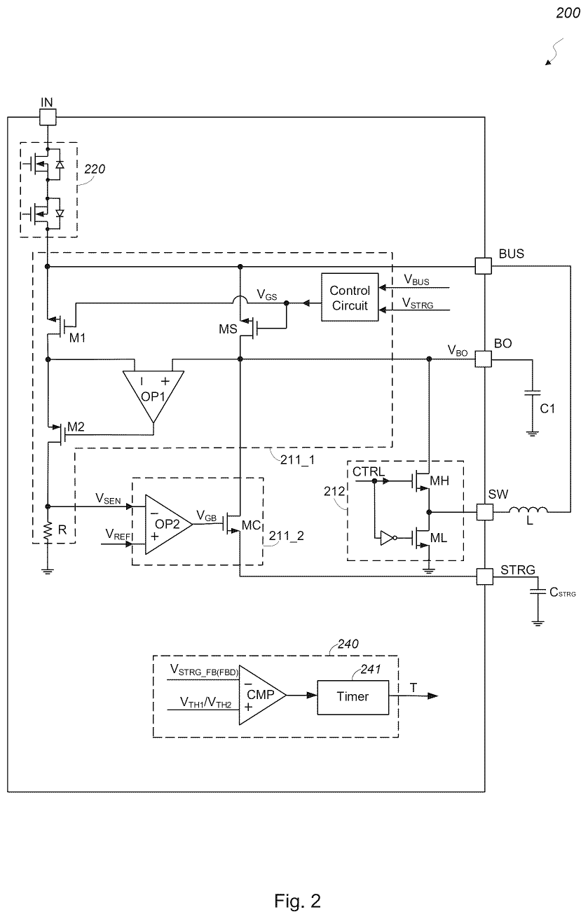

FIG. 2 illustrates a circuit schematic of a power management circuit 200 according to an embodiment of the present invention. The power management circuit 200 shows a specific implementation of the power management circuit 100 shown in FIG. 1.

As shown in FIG. 2, the power management circuit 200 includes an input protection circuit 220, a current sensing circuit 211_1, a current control circuit 211_2, and a switching circuit 212. The input protection circuit 220 is an implementation of the input protection circuit 120 described in FIG. 1. The combination of the current sensing circuit 211_1 and the current control circuit 211_2 is an implementation of the first charging path 111 described in FIG. 1. The combination of the switching circuit 212 and the current control circuit 211_2 is an implementation of the second charging path 112 described in FIG. 1.

The current sensing circuit 211_1 is configured to sense the constant charging current I_{CH} supplied to the power loss protection capacitor C_{STRG} during the first charging phase, and generate a current sensing signal V_{SEN} being indicative of the constant charging current I_{CH}. As shown in FIG. 2, the current sensing circuit 211_1 includes: a current sensing transistor MS, a first transistor M1, a second transistor M2, a first operational amplifier OP1 and a resistor R. A source of the current sensing transistor MS is coupled to the bus terminal BUS, a drain of the current sensing transistor MS is coupled to a bias terminal BO and a gate of the current sensing transistor MS is configured to receive a gate control signal V_{GS} generated by the control circuit. The gate control signal V_{GS} is configured to control the ON and OFF of the current sensing transistor MS. In the embodiment shown in FIG. 2, the control circuit compares the energy storage voltage V_{STRG} across the power loss protection capacitor C_{STRG} with the bus voltage V_{BUS}, and when the energy storage voltage V_{STRG} is below the bus voltage V_{BUS} and a difference between the two exceeds the aforementioned predetermined threshold (e.g., 0.3 V), the gate control signal Ves controls the current sensing transistor MS to be turned on. When the energy storage voltage V_{STRG} is below the bus voltage V_{BUS} and a difference between the two is less than the aforementioned predetermined threshold (e.g., 0.3 V), or V_{STRG} exceeds the bus voltage V_{BUS}, the gate control signal V_{GS} controls the current sensing transistor MS to be turned off. The first transistor M1 has a source coupled to the bus terminal BUS, a gate coupled to the gate of the current sensing transistor MS, and a drain coupled to a first input terminal of the first operational amplifier OP1. The second transistor M2 has a source coupled to the drain of the first transistor M1, and a gate coupled to an output terminal of the first operational amplifier OP1. A second input terminal of the first operational amplifier OP1 is coupled to the bias terminal BO. The resistor R is coupled between the drain of the second transistor M2 and a reference ground terminal and generates the current sensing signal V_{SEN} being indicative of the constant charging current I_{CH}.

The current control circuit 211_2 is configured to control the magnitude of the constant charging current I_{CH}. As shown in FIG. 2, the current control circuit 211_2 includes a current control transistor MC and a second operational amplifier OP2. The current control transistor MC is coupled between the bias terminal BO and the energy storage terminal STRG. The current control transistor MC has a source coupled to the energy storage terminal STRG and a drain coupled to the bias terminal BO. The second operational amplifier OP2 receives the current sensing signal V_{SEN} at its first input terminal and a reference voltage V_{REF} at its second input terminal, and generates a current control signal V_{GB} based on the current sensing signal V_{SEN} and the reference voltage V_{REF}. The current control signal V_{GB} is provided to the gate of the current control transistor MC to maintain the constant charging current I_{CH} at a predetermined value indicated by the reference voltage V_{REF}. For example, the magnitude of the constant charging current I_{CH} may be changed by adjusting a magnitude of the reference voltage V_{REF}. The working principle of the current control circuit 211_2 for controlling the constant charging current I_{CH} is that: when the constant charging current I_{CH} increases, the current sensing signal V_{SEN} being indicative of the constant charging current I_{CH} increases, causing the current control signal V_{GB} to decrease and a gate-source voltage of the current control transistor MC to decrease, thereby decreasing the constant charging current I_{CH}.

It should be understood that the specific structures of the current sensing circuit 211_1 and the current control circuit 211_2 shown in FIG. 2 are not limited to those illustrated, and any circuit capable of sensing or regulating the constant charging current I_{CH} is covered by the present invention.

Continuing the description of FIG. 2, the switching circuit 212 includes a high-side switch MH and a low-side switch ML. During the first charging phase, both the high-side switch MH and the low-side switch ML are turned off, resulting in zero current through the inductor L. During the second charging phase, a charging current to the power loss protection capacitor C_{STRG} is provided by controlling the ON and OFF of the high-side switch MH and the low-side switch ML, and the bus voltage V_{BUS} is converted into a bias voltage V_{BO}. Specifically, during the second charging phase, the charging current flows from the bus terminal BUS to the bias terminal BO sequentially through the inductor L and the switching circuit 212, then through the current control transistor MC to the energy storage terminal STRG to charge the power loss protection capacitor C_{STRG}, while the current sensing transistor MS is turned off.

It should be understood that the specific structure of the switching circuit 212 shown in FIG. 2 is not limited to that illustrated, and any circuit capable of sensing or regulating the constant charging current I_{CH} is covered by the present invention.

In an embodiment of the present invention, the power management circuit 100 (or 200) may be configured to obtain a capacitance value of the power loss protection capacitor C_{STRG} (or a parameter for calculating the capacitance value) during the startup process. Specifically, as shown in FIG. 1, the power management circuit 100 may further include a capacitance monitoring circuit 140 configured to monitor the energy storage voltage V_{STRG} during charging of the power loss protection capacitor C_{STRG} via the first charging path 111 during the startup process of the power management circuit 100, and to obtain the capacitance value of the power loss protection capacitor C_{STRG} (or the parameter for calculating the capacitance value) based on the monitored energy storage voltage V_{STRG}. For example, the power management circuit 100 may further include a voltage feedback circuit (not shown) coupled to the energy storage terminal STRG and is configured to transmit an energy storage voltage feedback signal V_{STRG_FB} being indicative of the energy storage voltage V_{STRG} to the capacitance monitoring circuit 140. For example, the energy storage voltage feedback signal V_{STRG_FB} may be proportional to the energy storage voltage V_{STRG} by a predetermined ratio. For another example, the energy storage voltage feedback signal V_{STRG_FB} may equal to the energy storage voltage V_{STRG}. In an embodiment, the power management circuit 100 may further include an analog-to-digital conversion circuit (not shown) configured to convert the energy storage voltage feedback signal V_{STRG_FB} into a digital signal V_{STRG_FBD} being indicative of the magnitude of the energy storage voltage feedback signal V_{STRG_FB}. In an embodiment, the capacitance monitoring circuit 140 may monitor the energy storage voltage V_{STRG} based on the energy storage voltage feedback signal V_{STRG_FB} (or the digital signal V_{STRG_FBD} thereof) and obtain the capacitance value of the power loss protection capacitor C_{STRG} (or the parameter for calculating the capacitance value) based on the monitoring results.

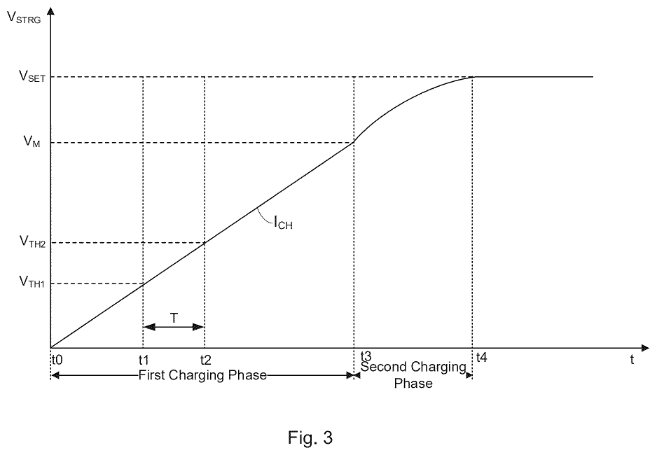

In an embodiment, the power management circuit 100 (or 200) may be configured to obtain the capacitance value of the power loss protection capacitor C_{STRG} (or the parameter for calculating the capacitance value) based on a relationship between the monitored energy storage voltage V_{STRG} and time during the constant current charging at startup. The process by which the capacitance monitoring circuit 140 (or 240) obtains the parameter for calculating the capacitance value of the power loss protection capacitor C_{STRG} will be described with reference to FIG. 3.

FIG. 3 illustrates a waveform diagram of the energy storage voltage V_{STRG} over time during the charging period of the power loss protection capacitor C_{STRG} by the first charging path (e.g., 111 shown in FIG. 1 or 211_1 and 211_2 shown in FIG. 2) and the second charging path (e.g., 112 shown in FIG. 1 or 212 and 211_2 shown in FIG. 2) at startup of the power management circuit 100 (or 200) according to an embodiment of the present invention. In the embodiment described with reference to FIG. 3, the set voltage V_{SET} of the power loss protection capacitor C_{STRG} is higher than the bus voltage V_{BUS}.

As shown in FIG. 3, during the first charging phase (t0˜t3), the power management circuit 100 (or 200) charges the power loss protection capacitor C_{STRG} using the constant charging current I_{CH} provided by the first charging path. During the first charging phase, the energy storage voltage V_{STRG} rises at a fixed slope. The rising slope of the energy storage voltage V_{STRG} may be adjusted by controlling the magnitude of the constant charging current I_{CH}. In an embodiment, the value being indicative of the magnitude of the constant charging current I_{CH} may be a predetermined value or a user-programmable value, i.e., it may be a known parameter. For example, the value being indicative of the magnitude of the constant charging current I_{CH} may be pre-stored in a register in the power management circuit 100 for subsequent use. For example, the current control circuit may control the magnitude of the constant charging current I_{CH} based on this value.

At the time t0, for example, when the power management circuit 100 is just powered on, the power loss protection capacitor C_{STRG} has not yet stored energy (or contains only a small amount of initial energy), the power loss protection capacitor C_{STRG} is first charged by the first charging path. When the first charging path is charging, the second charging path is not working. That is, the time required for the voltage V_{STRG} to rise to the intermediate charging voltage V_{M} may be controlled by adjusting the magnitude of the constant charging current I_{CH}. The energy storage voltage V_{STRG} rises to a first threshold voltage V_{TH1} at the time t1, and rises to a second threshold voltage V_{TH2} at the time t2 and further rises to the intermediate charging voltage V_{M} at the time t3, then the first charging phase ends.

Subsequently, starting from the time t3, the power management circuit 100 continues charging the power loss protection capacitor C_{STRG} via the second charging path. When the second charging path is used for charging, the first charging path stops working. The energy storage voltage V_{STRG} rises to the set voltage V_{SET} at the time t4, then the second charging phase ends.

Referring back to FIG. 1 and FIG. 2, in an embodiment, the capacitance monitoring circuit 140 (or 240) is configured to monitor the energy storage voltage V_{STRG} and provide the time period T between the energy storage voltage V_{STRG} rises from the first threshold voltage V_{TH1} to the second threshold voltage V_{TH2}. In this embodiment, the parameter for calculating the capacitance value of the power loss protection capacitor C_{STRG} may include the time period T. For example, as shown in FIG. 2, the capacitance monitoring circuit 140 (or 240) may include a comparing circuit CMP configured to determine whether the energy storage voltage V_{STRG} reaches the first threshold voltage V_{TH1} and whether it reaches the second threshold voltage V_{TH2} based on the energy storage voltage feedback signal V_{STRG_FB} (or the digital signal V_{STRG_FBD} thereof) received from the feedback circuit. Further, the capacitance monitoring circuit 140 (or 240) further includes a timer 241 that starts timing when the energy storage voltage V_{STRG} reaches the first threshold voltage V_{TH1} and stops timing when the energy storage voltage V_{STRG} reaches the second threshold voltage V_{TH2}, so as to obtain the time period T=t2−t1 between the energy storage voltage V_{STRG} rises from the first threshold voltage V_{TH1} to the second threshold voltage V_{TH2}. In an embodiment, the first threshold voltage V_{TH1} is lower than the second threshold voltage V_{TH2}, and both the first threshold voltage V_{TH1} and the second threshold voltage V_{TH2} are lower than the intermediate voltage V_{M}. In an embodiment, the first threshold voltage V_{TH1} and the second threshold voltage V_{TH2} may be predetermined values or user-programmable values, i.e., they may be known parameters. In an embodiment, the values of the first threshold voltage V_{TH1} and the second threshold voltage V_{TH2} may be pre-stored in a register (not shown) in the power management circuit 100 for subsequent use. In another embodiment, the difference between the first threshold voltage V_{TH1} and the second threshold voltage V_{TH2} (V_{TH2}−V_{TH1}) may be pre-stored in a register (not shown) in the power management circuit 100 for subsequent use.

In an embodiment, the capacitance monitoring circuit 140 (or 240) may be further configured to obtain the capacitance value of the power loss protection capacitor C_{STRG} based on: the constant charging current I_{CH}, the time period T between the energy storage voltage V_{STRG} rises from the first threshold voltage V_{TH1} to the second threshold voltage V_{TH2}, the first threshold voltage V_{TH1}, and the second threshold voltage V_{TH2} (or the difference between the second threshold voltage V_{TH2} and the first threshold voltage V_{TH1}).

In an embodiment, the capacitance monitoring circuit 140 (or 240) may obtain the capacitance value C of the power loss protection capacitor C_{STRG} based on the following equation (1):

$$C = {I}_{CH} * T / ( {V}_{T H {2}^{-}} {V}_{T H 1} ) . \qquad ( 1 )$$

For example, the capacitance monitoring circuit 140 (or 240) may include a digital circuit module to calculate the capacitance value C of the power loss protection capacitor C_{STRG} based on the above equation (1).

In an embodiment, the power management circuit 100 may further include a communication module (not shown) and an output terminal (not shown) configured to transmit: the constant charging current I_{CH}, the time period T between the energy storage voltage V_{STRG} rises from the first threshold voltage V_{TH1} to the second threshold voltage V_{TH2}, the first threshold voltage V_{TH1}, and the second threshold voltage V_{TH2} (or the difference between the second threshold voltage V_{TH2} and the first threshold voltage V_{TH1}) to an external computing device (e.g., a microcontroller unit, MCU, or a host including the MCU) for calculating the capacitance value C of the power loss protection capacitor C_{STRG}.

In a conventional capacitance test method, the capacitance monitoring function of a power loss protection (PLP) power management integrated circuit is typically used, to first charge the power loss protection capacitor to a predetermined voltage with a relatively high voltage value, and after the power management circuit enters a stable work state, a capacitance monitoring mode is enabled. The capacitance value of the power loss protection capacitor is then obtained by discharging the capacitor through an additional discharge circuit. This conventional test method results in waste of charging and discharging time and energy.

Compared with conventional capacitance test methods, the capacitance monitoring method according to embodiments of the present invention uses the existing charging circuit in the power management circuit to obtain the capacitance value of the power loss protection capacitor during the existing pre-charging phase. That is, the capacitance monitoring method according to embodiments of the present invention neither require a dedicated discharge circuit or dedicated monitoring operations/periods, nor cause energy loss due to dedicated discharging, thereby minimizing the impact of capacitance monitoring operations on normal functionality. Additionally, the capacitance monitoring scheme according to embodiments of the present invention can pre-calculate an initial capacitance value of the power loss protection capacitor during the startup process of the power management circuit, providing a reference value for health monitoring of the power loss protection capacitor when the power management circuit subsequently enters the steady operation state.

In practical applications, the actual charging current flowing into the power loss protection capacitor C_{STRG} includes not only the constant charging current I_{CH} provided by the first charging path but also the leakage current of the power loss protection capacitor C_{STRG} and other currents from other circuits related to the power loss protection capacitor C_{STRG}, which are collectively referred to as leakage current I_{LKG} hereinafter.

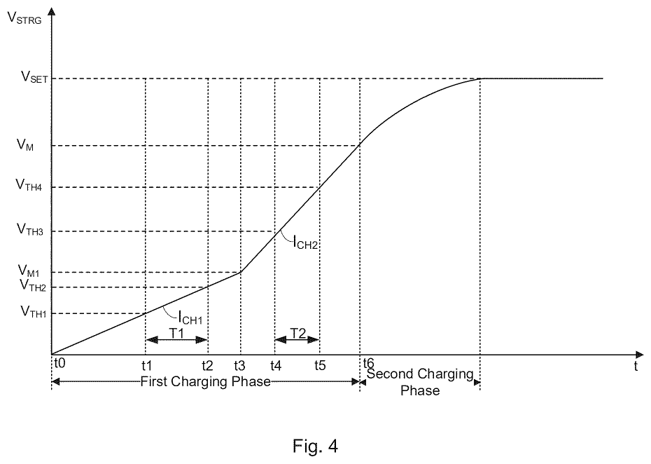

Based on this, to eliminate a capacitance calculation error caused by the leakage current I_{LKG}, an improved power management circuit and capacitance calculation method is provided according to the embodiments of the present invention, which will now be described with reference to FIG. 4.

FIG. 4 illustrates a waveform diagram of the energy storage voltage V_{STRG} over time during charging of the power loss protection capacitor C_{STRG} through the first charging path (e.g., 111 shown in FIG. 1 or 211_1 and 211_2 shown in FIG. 2) and the second charging path (e.g., 112 shown in FIG. 1 or 212 and 211_2 shown in FIG. 2) during the startup process of the power management circuit 100 (or 200) according to an embodiment of the present invention. In the embodiment described with reference to FIG. 4, the set voltage V_{SET} of the power loss protection capacitor C_{STRG} is higher than the bus voltage V_{BUS}.

In the embodiment shown in FIG. 4, the first charging path may charge the power loss protection capacitor C_{STRG} by two different constant currents during the first charging phase. As shown in FIG. 4, between the time to and the time t3, the first charging path charges the power loss protection capacitor C_{STRG} by a first constant charging current I_{CH1} to boost the voltage of the power loss protection capacitor C_{STRG} to the first intermediate voltage V_{M1}. Between the time t3 and the time t6, the first charging path provides a second constant charging current I_{CH2} to charge the power loss protection capacitor C_{STRG} to the intermediate voltage V_{M}. For convenience of description, the period during which the power loss protection capacitor C_{STRG} is charged by the first constant charging current I_{CH1} may be referred to as a first constant charging period (shown in FIG. 4 as the period from the time t0 to the time t3), and the period during which the power loss protection capacitor C_{STRG} is charged by the second constant charging current I_{CH2} may be referred to as a second constant charging period (shown in FIG. 4 as the period from the time t3 to the time t6).

In an embodiment, the capacitance monitoring circuit 140 (or 240) may monitor the energy storage voltage V_{STRG} during both the first constant charging period and the second constant charging period, and obtain the capacitance value of the power loss protection capacitor C_{STRG} (or the parameter for calculating the capacitance value) based on the monitored energy storage voltage V_{STRG}.

Referring to FIG. 4, during the first constant charging period, the energy storage voltage V_{STRG} rises to the first threshold voltage V_{TH1} at the time t1 and to the second threshold voltage V_{TH2} at the time t2. In an embodiment, the capacitance monitoring circuit 140 (or 240) may be configured to sense the energy storage voltage V_{STRG} based on the energy storage voltage feedback signal V_{STRG_FB} (or the digital signal V_{STRG_FBD} thereof) being indicative of the energy storage voltage V_{STRG}, and provide a time period T1 for the energy storage voltage V_{STRG} to rise from the first threshold voltage V_{TH1} to the second threshold voltage V_{TH2}. In this embodiment, the parameter for calculating the capacitance value of the power loss protection capacitor C_{STRG} includes the time period T1.

In an embodiment, the comparing circuit in the capacitance monitoring circuit 140 (or 240) determines whether the energy storage voltage V_{STRG} reaches the first threshold voltage V_{TH1} and whether it reaches the second threshold voltage V_{TH2} based on the V_{STRG_FB} (or the digital signal V_{STRG_FBD} thereof) received from the feedback circuit.

In an embodiment, the timer in the capacitance monitoring circuit 140 (or 240) starts timing when it is determined that the energy storage voltage V_{STRG} reaches the first threshold voltage V_{TH1} and stops timing when it is determined that the energy storage voltage V_{STRG} reaches the second threshold voltage V_{TH2}, thereby obtaining the time period T1=t2−t1 for the energy storage voltage V_{STRG} to rise from the first threshold voltage V_{TH1} to the second threshold voltage V_{TH2}. The first threshold voltage V_{TH1} is lower than the second threshold voltage V_{TH2}, and both the first threshold voltage V_{TH1} and the second threshold voltage V_{TH2} are lower than the first intermediate voltage V_{M1}. In an embodiment, the first threshold voltage V_{TH1} and the second threshold voltage V_{TH2} may be predetermined values or user-programmable values, i.e., they may be known parameters. In an embodiment, the values of the first threshold voltage V_{TH1} and the second threshold voltage V_{TH2} may be pre-stored in a register (not shown) in the power management circuit 100 for subsequent use. In another embodiment, the difference between the first threshold voltage V_{TH1} and the second threshold voltage V_{TH2} (V_{TH2}−V_{TH1}) may be pre-stored in a register (not shown) in the power management circuit 100 for subsequent use.

Considering the leakage current I_{LKG}, between the time t1 and the time t2, the change value ΔQ1 of the charge amount on the power loss protection capacitor C_{STRG}, can be expressed by the following equation:

$$Δ Q 1 = C * ( {V}_{TH 2} - {V}_{TH 1} ) = ( {I}_{C H 1} - {I}_{L K G} ) ⋆ T 1. \qquad ( 2 )$$

Continuing with reference to FIG. 4, during the second constant charging period, the first charging path charges the power loss protection capacitor C_{STRG} to the intermediate voltage V_{M} by providing a second constant charging current I_{CH2}. In an embodiment, there is a proportional relationship between the second constant charging current I_{CH2} and the first constant charging current I_{CH1}. For example.

$${I}_{CH 2} = K 1 * {I}_{CH 1} , where K 1 \neq 1. \qquad ( 3 )$$

The energy storage voltage V_{STRG} rises to a third threshold voltage V_{TH3} at the time t4 and rises to a fourth threshold voltage V_{TH4} at the time t5. In an embodiment, the capacitance monitoring circuit 140 (or 240) may be configured to provide a time period T2 for the energy storage voltage V_{STRG} to rise from the third threshold voltage V_{TH3} to the fourth threshold voltage V_{TH4} based on the energy storage voltage feedback signal V_{STRG_FB} (or the digital signal V_{STRG_FBD} thereof). In this embodiment, the parameter for calculating the capacitance value of the power loss protection capacitor C_{STRG} may further include the time period T2.

In an embodiment, the aforementioned comparing circuit may be configured to determine whether the energy storage voltage V_{STRG} reaches the third threshold voltage V_{TH3} and whether it reaches the fourth threshold voltage V_{TH4} based on the energy storage voltage feedback signal V_{STRG_FB} (or the digital signal V_{STRG_FBD} thereof) received from the feedback circuit. The aforementioned timer (not shown) may be configured to start timing when the energy storage voltage V_{STRG} reaches the third threshold voltage V_{TH3} and stop timing when the energy storage voltage V_{STRG} reaches the fourth threshold voltage V_{TH4}, thereby obtaining the time period T2=t5-t4 for the energy storage voltage V_{STRG} to rise from the third threshold voltage V_{TH3} to the fourth threshold voltage V_{TH4}. In an embodiment, the third threshold voltage V_{TH3} is lower than the fourth threshold voltage V_{TH4}, and both the third threshold voltage V_{TH3} and the fourth threshold voltage V_{TH4} are lower than the intermediate voltage V_{M}. In an embodiment, the third threshold voltage V_{TH3} and the fourth threshold voltage V_{TH4} may be predetermined values or user-programmable values, i.e., they may be known parameters. In an embodiment, the values of the third threshold voltage V_{TH3} and the fourth threshold voltage V_{TH4} may be pre-stored in a register (not shown) in the power management circuit 100 for subsequent use. In another embodiment, the difference between the third threshold voltage V_{TH3} and the fourth threshold voltage V_{TH4} (V_{TH4}−V_{TH3}) may be pre-stored in a register (not shown) in the power management circuit 100 for subsequent use.

In an embodiment, the difference between the fourth threshold voltage V_{TH4} and the third threshold voltage V_{TH3} is proportional to the difference between the second threshold voltage V_{TH2} and the first threshold voltage V_{TH1}. For example, V_{TH4}−V_{TH3}=K2×(V_{TH2}−V_{TH1}) (4). For convenience of description, K2=1 is used as an example for description below.

Considering the presence of leakage current I_{LKG} in the power loss protection capacitor C_{STRG}, the change value ΔQ2 of the charge amount on the power loss protection capacitor C_{STRG} between the time t4 and the time t5 can be expressed by the following equation:

$$Δ Q 2 = C * ( {V}_{TH 4} - {V}_{TH 3} ) = ( {I}_{CH 2} - {I}_{L K G} ) ⋆ T 2. \qquad ( 5 )$$

Combining equations (2)˜(5), the expression for the capacitance C of the power loss protection capacitor C_{STRG} can be obtained:

$$C = ( K 1 - 1 ) * T 1 * T 2 * {I}_{CH 1} / ( T 1 - T 2 ) * ( {V}_{TH 2} - {V}_{TH 1} ) . \qquad ( 6 )$$

It should be understood that, for ease of description, the above equation (6) is derived with K2=1 as an example. Using similar principles as the aforementioned derivation, the expression for the capacitance C when K2 is not equal to 1 can be derived, which will not be described hereinafter.

In an embodiment, the capacitance monitoring circuit 140 (or 240) is further configured to obtain the capacitance value C of the power loss protection capacitor C_{STRG} based on: the first constant charging current I_{CH1}, the ratio K1 between the second constant charging current I_{CH2} and the first constant charging current I_{CH1}, the time period T1 for the energy storage voltage V_{STRG} to rise from the first threshold voltage V_{TH1} to the second threshold voltage V_{TH2}, the time period T2 for the energy storage voltage V_{STRG} to rise from the third threshold voltage V_{TH3} to the fourth threshold voltage V_{TH4}, the first threshold voltage V_{TH1}, and the second threshold voltage V_{TH2} (or the difference between the second threshold voltage V_{TH2} and the first threshold voltage V_{TH1}).

In an embodiment, the capacitance monitoring circuit 140 (or 240) may include a programmable logic module such as a digital circuit module, thus to calculate the capacitance value C of the power loss protection capacitor C_{STRG} based on the aforementioned equation (6).

In an embodiment, the capacitance monitoring circuit 140 (or 240) may further include a communication module (not shown) and an output terminal (not shown) configured to transmit: the first constant charging current I_{CH1}, the ratio K1 between the second constant charging current I_{CH2} and the first constant charging current I_{CH1}, the time period T1 for the energy storage voltage V_{STRG} to rise from the first threshold voltage V_{TH1} to the second threshold voltage V_{TH2}, the time period T2 for the energy storage voltage V_{STRG} to rise from the third threshold voltage V_{TH3} to the fourth threshold voltage V_{TH4}, the first threshold voltage V_{TH1}, and the second threshold voltage V_{TH2} (or the difference between the second threshold voltage V_{TH2} and the first threshold voltage V_{TH1}) to an external computing device (e.g., a microcontroller unit, MCU, or a host including the MCU) for calculating the capacitance value C of the power loss protection capacitor C_{STRG}.

Thus, to charge the power loss protection capacitor C_{STRG} by two different constant charging currents (I_{CH1} and I_{CH2}), the influence of the leakage current caused by the power loss protection capacitor C_{STRG} can be eliminated so as to get a more accurate capacitance value.

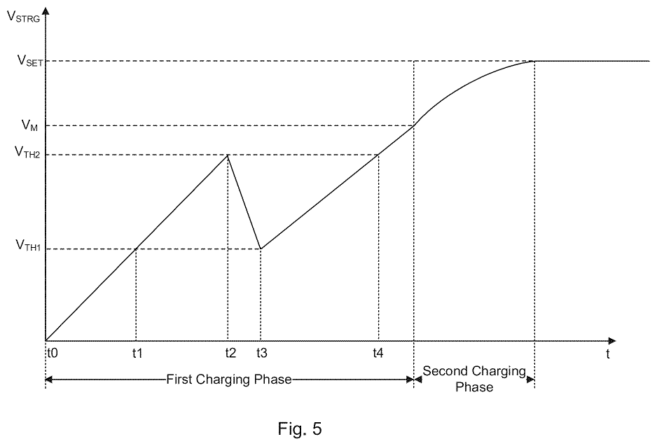

FIG. 5 illustrates a waveform diagram of the energy storage voltage V_{STRG} over time during charging of the power loss protection capacitor C_{STRG} by the first charging path 111 and the second charging path 112 shown in FIG. 1 during the startup process of the power management circuit 100 (or 200) according to an embodiment of the present invention. In the embodiment described with reference to FIG. 5, the set voltage V_{SET} of the power loss protection capacitor C_{STRG} is higher than the bus voltage V_{BUS}.

Compared with the embodiment shown in FIG. 4, the difference is that after the energy storage voltage V_{STRG} is increased to the second threshold voltage V_{TH2} by the first constant charging current I_{CH1}, the power loss protection capacitor C_{STRG} is firstly discharged to the first threshold voltage V_{TH1} then the energy storage voltage V_{STRG} IS charged from the first threshold voltage V_{TH1} to the intermediate voltage V_{M} by the second constant charging current I_{CH2}. Thus, the capacitance value C of the power loss protection capacitor C_{STRG} can be obtained based on the same principle as the derivation in FIG. 4, and compared with the embodiment shown in FIG. 4, it is unnecessary to set the fourth threshold voltage V_{TH4} and the third threshold voltage V_{TH3}, so that the circuit design is simpler.

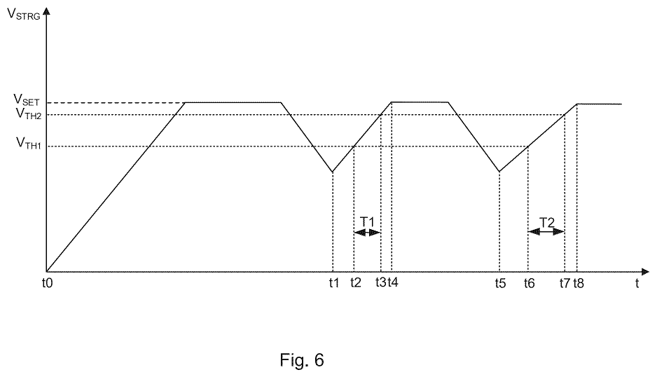

FIG. 6 shows a waveform diagram of the energy storage voltage V_{STRG} over time during the constant current charging of the power loss protection capacitor C_{STRG} by the first charging path 111 shown in FIG. 1 during the stable operation of the power management circuit 100 (or 200) according to still another embodiment of the present invention.

In the embodiment shown in FIG. 6, the set voltage V_{SET} of the power loss protection capacitor C_{STRG} is equal to or lower than the bus voltage V_{BUS}, therefore, the power management circuit 100 may charge the power loss protection capacitor C_{STRG} solely by the first charging path 111, and boost the energy storage voltage V_{STRG} across the power loss protection capacitor C_{STRG} to the set voltage V_{SET}.

As shown in FIG. 6, the power management circuit 100 may be configured to perform two discharging and charging processes on the power loss protection capacitor C_{STRG} after elevating the energy storage voltage V_{STRG} to the set voltage V_{SET}. During the two charging processes (e.g., t1˜t4 and t5˜t8), the power management circuit 100 provides two different constant charging currents respectively to charge the power loss protection capacitor C_{STRG} by the first charging path 111. For example, the constant charging current in the two constant charging processes has a proportional relationship as illustrated in equation (3). Similar to the aforementioned derivation of the same principle, the capacitance value of the power loss protection capacitor C_{STRG} may be obtained based on a change relationship between time and the voltage of the power loss protection capacitor C_{STRG} between the two constant charging periods, and details are not described herein again.

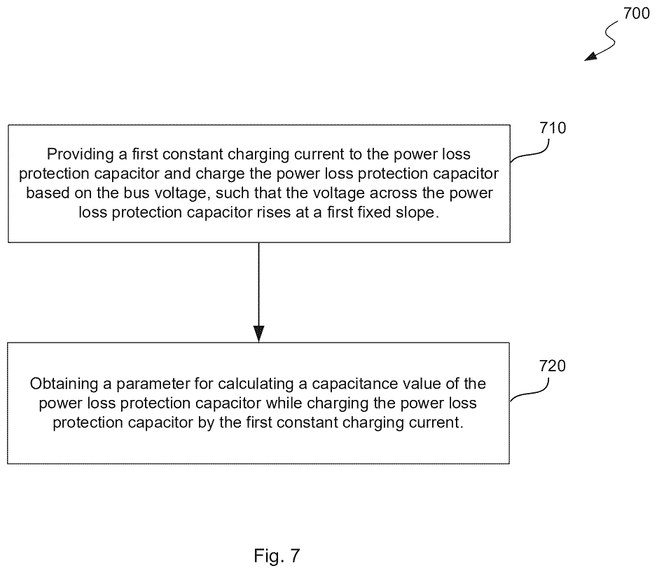

FIG. 7 shows a flowchart of a method 700 for monitoring a capacitance value of a power loss protection capacitor according to an embodiment of the present invention. The method 700 may be performed by the power management circuit 100 described above with reference to FIG. 1-FIG. 2. The power management circuit 100 may comprise multiple circuits packaged together as a single integrated circuit die. Method 700 may include the following steps:

Step 710: during a startup process of the integrated circuit, providing a first constant charging current to the power loss protection capacitor and charge the power loss protection capacitor based on the bus voltage, such that the voltage across the power loss protection capacitor rises at a first fixed slope;

Step 720: during the startup process of the integrated circuit, monitoring the voltage across the power loss protection capacitor while charging the power loss protection capacitor by the first constant charging current to obtain a parameter for calculating a capacitance value of the power loss protection capacitor.

The power management circuit with power loss protection function and the method for monitoring the capacitance value of the power loss protection capacitor disclosed by the present invention can use the existing charging circuit in the power management circuit to obtain the capacitance value of the power loss protection capacitor, that is, the capacitance monitoring method according to embodiments of the present invention neither require a dedicated discharge circuit nor cause energy loss due to dedicated discharging, thereby minimizing the impact of monitoring operations on normal function. Additionally, the capacitance monitoring method according to embodiments of the present invention can pre-calculate the initial capacitance value of the power loss protection capacitor during the startup process of the power management circuit, providing an accurate reference value for subsequent health monitoring of the power loss protection capacitor.

Those skilled in the art will understand that the present disclosure is not limited to the specific embodiments particularly shown and described herein. Rather, the scope of the present disclosure is defined by the claims, and includes combinations and sub-combinations of the features described above, as well as variations and modifications that would occur to those skilled in the art upon reading the aforementioned description and which are not disclosed in the prior art.

1. An integrated circuit with power loss protection function, comprising:
a bus terminal configured to provide a bus voltage;
an energy storage terminal configurable to be coupled to a power loss protection capacitor;
a charging circuit, coupled between the bus terminal and the energy storage terminal, configured to charge the power loss protection capacitor with the bus voltage when the power loss protection capacitor is coupled to the energy storage terminal, wherein the charging circuit comprises a first charging path configured to charge the power loss protection capacitor based on the bus voltage during a charging period in a startup process of the integrated circuit, and wherein the charging period includes at least a first constant charging period during which the first charging path is further configured to at least provide a first constant charging current to charge the power loss protection capacitor, such that a voltage across the power loss protection capacitor rises at a first fixed slop; and
a capacitance monitoring circuit configured to monitor a voltage across the power loss protection capacitor when the power loss protection capacitor is coupled to the energy storage terminal, in the charging period of the startup process of the integrated circuit, to obtain a parameter for calculating a capacitance value of the power loss protection capacitor.

2. The integrated circuit of claim 1, wherein the capacitance monitoring circuit is further configured to, during the first constant charging period, obtain a first time period for the voltage across the power loss protection capacitor to rise from a first threshold voltage to a second threshold voltage, and wherein the second threshold voltage is higher than the first threshold voltage, and wherein the parameter comprises the first time period.

3. The integrated circuit of claim 2, wherein the capacitance monitoring circuit is further configured to obtain the capacitance value of the power loss protection capacitor at least based on the first time period, the first threshold voltage, the second threshold voltage, and the first constant charging current.

4. The power management circuit of claim 2, wherein the capacitance monitoring circuit is configured to obtain the capacitance value of the power loss protection capacitor at least based on the following equation:
$$C = {I}_{CH 1} * T 1 / ( {V}_{TH 2} - {V}_{T H 1} ) ,$$
and wherein the C represents the capacitance value of the power loss protection capacitor, the I_{CH1} represents the first constant charging current value, the V_{TH1} represents the first threshold voltage, the V_{TH2} represents the second threshold voltage, and the T1 represents the first time period.

5. The integrated circuit of claim 1, wherein the charging period further includes a second constant charging period; and wherein
the first charging path is further configured to provide a second constant charging current during the second constant charging period to the power loss protection capacitor to charge the power loss protection capacitor such that the voltage across the power loss protection capacitor rises at a second fixed slope; and wherein
the first constant charging current and the second constant charging current are unequal and proportional.

6. The integrated circuit of claim 5, wherein the capacitance monitoring circuit is configured to obtain a first time period for the voltage across the power loss protection capacitor to rise from the first threshold voltage to the second threshold voltage during the first constant charging period, and obtain a second time period for the voltage across the power loss protection capacitor to rise from a third threshold voltage to a fourth threshold voltage during the second constant charging period, and wherein the parameter comprises the first time period and the second time period, and wherein the fourth threshold voltage is higher than the third threshold voltage, and the second threshold voltage is higher than the first threshold voltage.

7. The integrated circuit of claim 6, wherein the third threshold voltage is equal to the first threshold voltage and the fourth threshold voltage is equal to the third threshold voltage.

8. The integrated circuit of claim 6, wherein a difference between the second threshold voltage and the first threshold voltage is proportional to a difference between the fourth threshold voltage and the third threshold voltage.

9. The integrated circuit of claim 6, wherein a difference between the second threshold voltage and the first threshold voltage is equal to a difference between the fourth threshold voltage and the third threshold voltage.

10. The integrated circuit of claim 9, wherein the capacitance monitoring circuit is configured to obtain the capacitance value of the power loss protection capacitor at least based on: the first time, the second time, the first threshold voltage, the second threshold voltage, the first constant charging current, and a ratio of the first constant charging current to the second constant charging current.

11. The integrated circuit according of 9, wherein the capacitance monitoring circuit is configured to obtain the capacitance value of the power loss protection capacitor based on the following equation:
$$C = ( K 1 - 1 ) * T 1 * T 2 * {I}_{CH 1} / ( T 1 - T 2 ) * ( {V}_{TH 2} - {V}_{TH 1} ) ,$$
and wherein the C represents a capacitance value of the power loss protection capacitor, the I_{CH1} represents the first constant charging current value, the K1 represents a ratio of the second constant charging current to the first constant charging current, the T1 represents the first time period, the T2 represents the second time period, the V_{TH1} represents the first threshold voltage, and the V_{TH2} represents the second threshold voltage.

12. A capacitance monitoring method for a power loss protection capacitor, the method being performed by an integrated circuit with a power loss protection function and comprising:
charging the power loss protection capacitor based on the bus voltage during a charging period in the startup process of the integrated circuit, and wherein the charging period includes at least a first constant charging period;
providing a first constant charging current to the power loss protection capacitor to charge the power loss protection capacitor during the first constant charging period, such that a voltage across the power loss protection capacitor rises at a first fixed slope; and
monitoring a voltage across the power loss protection capacitor in the charging period of the startup process of the integrated circuit, to obtain a parameter for calculating a capacitance value of the power loss protection capacitor.

13. The method of claim 12, wherein the obtaining parameter for calculating the capacitance value of the power loss protection capacitor comprising:
during the first constant charging period, obtaining a first time period for the voltage across the power loss protection capacitor to rise from a first threshold voltage to a second threshold voltage, and wherein the second threshold voltage is higher than the first threshold voltage, and wherein the parameter comprises the first time period.

14. The method of claim 13, further comprising:
obtaining the capacitance value of the power loss protection capacitor at least based on, the first time period, the first threshold voltage, the second threshold voltage, and the first constant charging current.

15. The method of claim 13, further comprising:
obtaining the capacitance value of the power loss protection capacitor at least based on the following equation:
$$C = {I}_{CH 1} * T 1 / ( {V}_{TH 2} - {V}_{T H 1} ) ,$$
wherein the C represents the capacitance value of the power loss protection capacitor, the I_{CH1} represents the first constant charging current value, the V_{TH1} represents the first threshold voltage, the V_{TH2} represents the second threshold voltage, and the T1 represents the first time period.

16. The method of claim 12, wherein the charging period further includes a second constant charging period; and wherein the method further comprises:
providing a second constant charging current during the second constant charging period to the power loss protection capacitor to charge the power loss protection capacitor such that the voltage across the power loss protection capacitor rises at a second fixed slope; and wherein
the first constant charging current and the second constant charging current are unequal and proportional.

17. The method of claim 16, further comprising:
during the first constant charging period, obtaining the first time period for the voltage across the power loss protection capacitor to rise from the first threshold voltage to the second threshold voltage, and during the second constant charging period, obtaining a second time period for the voltage across the power loss protection capacitor to rise from the third threshold voltage to the fourth threshold voltage, wherein the parameter comprises the first time period and the second time period, and wherein the fourth threshold voltage is higher than the third threshold voltage, and the second threshold voltage is higher than the first threshold voltage.

18. The method of claim 17, wherein the third threshold voltage is equal to the first threshold voltage and the fourth threshold voltage is equal to the third threshold voltage.

19. The method of claim 17, wherein a difference between the second threshold voltage and the first threshold voltage is proportional to a difference between the fourth threshold voltage and the third threshold voltage.

20. The method of claim 17, wherein a difference between the second threshold voltage and the first threshold voltage is equal to a difference between the fourth threshold voltage and the third threshold voltage.

21. The method of claim 20, further comprising:
obtaining the capacitance value of the power loss protection capacitor at least based on, the first time period, the second time period, the first threshold voltage, the second threshold voltage, the first constant charging current, and a ratio of the first constant charging current to the second constant charging current.

22. The method of claim 20, further comprising:
obtaining the capacitance value of the power loss protection capacitor based on the following equation:
$$C = ( K 1 - 1 ) * T 1 * T 2 * {I}_{CH 1} / ( T 1 - T 2 ) * ( {V}_{TH 2} - {V}_{TH 1} ) ,$$
wherein the C represents a capacitance value of the power loss protection capacitor, the I_{CH1} represents the first constant charging current value, the K1 represents a ratio of the second constant charging current to the first constant charging current, the T1 represents the first time period for the voltage across the power loss protection capacitor to rise from the first threshold voltage to the second threshold voltage in the period during which the first charging path charges the power loss protection capacitor, the T2 represents the second time period for the voltage across the power loss protection capacitor to rise from the third threshold voltage to the fourth threshold voltage in the period during which the second charging path charges the power loss protection capacitor, the V_{TH1} represents the first threshold voltage, and the V_{TH2} represents the second threshold voltage.
